(19) United States
(12) Patent Application Publication
(10) Pub. No.: US 2019/0361769 A1
(43) Pub. Date: Nov. 28, 2019

(54) MEMORY DEVICE WITH SOFT-DECISION DECODING AND METHODS OF READING AND FORMING THEREOF

(71) Applicant: Agency for Science, Technology and Research, Singapore (SG)

(72) Inventors: Kheong Sann Chan, Singapore (SG); Zhiliang Qin, Singapore (SG)

(21) Appl. No.: 16/476,833

(22) PCT Filed: Jan. 12, 2018
(86) PCT No.: PCT/SG2018/050020

§ 371 Date: Jul. 9, 2019

(30) Foreign Application Priority Data
Jan. 12, 2017 (SG) 10201700242V

(51) Int. Cl. G06F 11/10; G11C 11/16; H03M 13/11; H03M 13/00

(52) U.S. Cl. CPC G06F 11/102; G11C 11/1673; H03M 13/6325; H03M 13/1102; G11C 11/1677

(57) ABSTRACT

There is provided a memory device including a memory cell configured to store an input data bit written thereto; a memory sensor configured to sense a parameter associated with a state of the memory cell; a detector configured to determine, based on the parameter sensed from the memory cell, a first soft information indicating the likelihood that the input data bit written to the memory cell is a predefined value; and a decoder configured to generate an output data bit of the memory cell based on the first soft information. In particular, the detector includes a first detector configured to determine the first soft information based on a second soft information indicating the likelihood that the state of the memory cell corresponds to a value of the input data bit written to the memory cell.

### CROSS-REFERENCE TO RELATED APPLICATION

This application claims the benefit of priority of Singapore Patent Application No. 10201700242V, filed 12 Jan. 2017, the contents of which are hereby incorporated by reference in their entirety for all purposes.

### TECHNICAL FIELD

Embodiments of the present invention generally relate to a memory device with soft-decision decoding, as well as a method of reading the memory device and a method of forming the memory device, and in particular, to a memory device with soft-decision decoding taking into account (e.g., factoring in) one or more types of errors which may be encountered in the memory device.

### BACKGROUND

Among solid-state non-volatile memory (NVM) technologies that have been developed to replace the traditional volatile dynamic random access memory (DRAM) in various applications, such as portable consumer electronics, data centers, computing systems, and so on, spin-torque transfer magnetoresistive random access memory (STT-MRAM) is viewed as one of the most promising technologies due to its scalability, speed, endurance, and power consumption.

In a STT-MRAM device, the reliability of the data recovered from the STT-MRAM device may be affected by various factors, such as but not limited to, variations of the magnetic tunneling junction (MTJ) resistances resulting from statistical parametric inconsistencies (e.g., inconsistencies in tunneling oxide thickness and cross-section area of the STT-MRAM cells in the STT-MRAM device); write errors (e.g., write failures) due to switching current distributions of the MTJ and insufficient write current caused by variations of the nMOS transistor; read errors (e.g., read failures) due to read disturbances and memory sensing inaccuracies, and so on. Though considerable efforts may have been made on improving the design of the STT-MRAM device and the wafer processing to fabricate the STT-MRAM cells, it appears that much less work has been done from a coding and signal processing perspective to correct errors encountered in STT-MRAM devices.

The state-of-art error correction codes (ECC) used for STT-MRAM devices are the simple Hamming codes or the BCH codes based on hard-decision decoding (HDD). In K. Cai, Z. Qin, and B. Chen, “Channel capacity and soft-decision decoding of LDPC codes for spin-torque transfer magnetic random access memory (STT-MRAM)”, Journal of Communications, vol. 8, no. 4, pages 225-232, April 2013 (hereinafter referred to as the Cai reference), low-density parity-check (LDPC) codes were investigated as a potential coding technique for STT-MRAM. It was shown in the Cai reference that LDPC codes based on soft-decision decoding provided a much better bit-error-rate (BER) and frame-error-rate (FER) performance over BCH codes, as well as achieving a significant improvement in terms of the maximum tolerable resistance spread.

For example, in the Cai reference, a channel model based on resistance spreads was used to characterize the probability distributions of MTJ resistances of the STT-MRAM cell. Such a channel model, however, does not consider one or more types of errors which may be encountered in the STT-MRAM device, for example, those which may be inevitably present in practical memory devices and may thus severely impair the overall performance of the ECC for the STT-MRAM device.

A need therefore exists to provide a memory device with soft-decision decoding that seeks to overcome, or at least ameliorate, one or more deficiencies of conventional memory devices, and in particular, to a memory device with soft-decision decoding that takes into account (e.g., factors in) one or more types of errors which may be encountered in the memory device so as to improve one or more aspects of the memory device, such as an improved error rate performance.

### SUMMARY

According to a first aspect of the present invention, there is provided a memory device comprising:
a memory cell configured to store an input data bit written thereto;
a memory sensor configured to sense a parameter associated with a state of the memory cell;
a detector configured to determine, based on the parameter sensed from the memory cell, a first soft information indicating the likelihood that the input data bit written to the memory cell is a predefined value; and
a decoder configured to generate an output data bit of the memory cell based on the first soft information,
wherein the detector comprises a first detector configured to determine the first soft information based on a second soft information indicating the likelihood that the state of the memory cell corresponds to a value of the input data bit written to the memory cell.

In various embodiments, the detector further comprises a second detector configured to determine the second soft information based on the parameter sensed from the memory cell.

In various embodiments, the first detector is configured to determine the first soft information based on a log-likelihood ratio of the input data bit based on the second soft information, and the second detector is configured to determine the second soft information based on a log-likelihood ratio of the state of the memory cell based on the parameter sensed from the memory cell.

In various embodiments, the likelihood of the input data bit being correctly written into the memory cell is represented by a binary symmetrical channel (BSC), and wherein the input data bit is an input to the BSC and the state of the memory cell is an output from the BSC.

In various embodiments, the second detector is further configured to determine the second soft information based on the first soft information fed back from the first detector, and the first detector is further configured to determine the first soft information based on a soft information of the output data bit fed back from the decoder.

In various embodiments, the detector further comprises a quantizer configured to convert the parameter sensed from the memory cell into a corresponding one of a plurality of quantization levels to produce a quantized parameter, wherein the detector is configured to determine the first soft information based on the quantized parameter.

In various embodiments, the detector further comprises a third detector configured to detect a read error of the memory cell based on the parameter sensed from the memory cell and to flag a corresponding data bit position as being affected by the read error if the read error of the memory cell is detected.

In various embodiments, the memory device comprises a plurality of memory cells configured to store input data bits of an input codeword written thereto, respectively, wherein the decoder comprises a read error corrector configured to receive a plurality of the first soft information determined with respect to the input data bits of the input codeword and to correct at least one of the plurality of the first soft information if the at least one first soft information corresponds to at least one data bit position flagged as being affected by the read error.

In various embodiments, the read error corrector is configured to correct the at least one first soft information based on, at a check node associated with a set of data bit positions in which only one data bit position thereof has been flagged as being affected by the read error, determining a new first soft information for replacing the first soft information corresponding to said one data bit position based on one or more bit-to-check inputs from respective one or more bit nodes to the check node, the respective one or more bit nodes corresponding to one or more data bit positions of the set of data bit positions not flagged as being affected by the read error.

In various embodiments, the memory device comprises a plurality of memory cells configured to store input data bits of an input low-density parity-check (LDPC) codeword written thereto, wherein
each of the plurality of memory cells is a spin-transfer torque magnetoresistive random access memory (STT-MRAM) cell,
the state of each of the plurality of memory cells is one of a high resistance state, a low resistance state, and a faulty state,
each of the input data bits has a predefined value of logic ‘1’ or logic ‘0’, and
the decoder is a LDPC decoder.

According to a second aspect of the present invention, there is provided a method of reading a memory device, the memory device comprising a memory cell configured to store an input data bit written thereto, the method comprising:
sensing a parameter associated with a state of the memory cell;
determining, based on the parameter sensed from the memory cell, a first soft information indicating the likelihood that the input data bit written to the memory cell is a predefined value; and
generating an output data bit of the memory cell based on the first soft information,
wherein said determining a first soft information comprises determining the first soft information based on a second soft information indicating the likelihood that the state of the memory cell corresponds to a value of the input data bit written to the memory cell.

In various embodiments, the second soft information is determined based on the parameter sensed from the memory cell.

In various embodiments, the first soft information is determined based on a log-likelihood ratio of the input data bit based on the second soft information, and the second soft information is determined based on a log-likelihood ratio of the state of the memory cell based on the parameter sensed from the memory cell.

In various embodiments, the likelihood of the input data bit being correctly written into the memory cell is represented by a binary symmetrical channel (BSC), and wherein the input data bit is an input to the BSC and the state of the memory cell is an output from the BSC.

In various embodiments, the second soft information is further determined based on the first soft information fed back from the first detector, and the first soft information is further determined based on a soft information of the output data bit fed back from the decoder.

In various embodiments, the method further comprises converting the parameter sensed from the memory cell into a corresponding one of a plurality of quantization levels to produce a quantized parameter, wherein the first soft information is determined based on the quantized parameter.

In various embodiments, the method further comprises detecting a read error of the memory cell based on the parameter sensed from the memory cell and flagging a corresponding data bit position as being affected by the read error if the read error of the memory cell is detected.

In various embodiments, the memory device comprises a plurality of memory cells configured to store input data bits of an input codeword written thereto, respectively, and wherein the method further comprises receiving a plurality of the first soft information determined with respect to the input data bits of the input codeword and correcting at least one of the plurality of the first soft information if the at least one first soft information corresponds to at least one data bit position flagged as being affected by the read error.

In various embodiments, the above-mentioned correcting at least one of the plurality of the first soft information comprises determining, at a check node associated with a set of data bit positions in which only one data bit position thereof has been flagged as being affected by the read error, a new first soft information for replacing the first soft information corresponding to said one data bit position based on one or more bit-to-check inputs from respective one or more bit nodes to the check node, the respective one or more bit nodes corresponding to one or more data bit positions of the set of data bit positions not flagged as being affected by the read error.

According to a third aspect of the present invention, there is provided a method of forming a memory device, the method comprises:
providing a memory cell configured to store an input data bit written thereto;
forming a memory sensor configured to sense a parameter associated with a state of the memory cell;
forming a detector configured to determine, based on the parameter sensed from the memory cell, a first soft information indicating the likelihood that the input data bit written to the memory cell is a predefined value; and
forming a decoder configured to generate an output data bit of the memory cell based on the first soft information,
wherein the detector comprises a first detector configured to determine the first soft information based on a second soft information indicating the likelihood that the state of the memory cell corresponds to a value of the input data bit written to the memory cell.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 depicts a schematic block diagram of a memory device according to various embodiments of the present invention;

FIG. 2 depicts a schematic block diagram of another memory device according to various embodiments of the present invention;

FIG. 3A depicts a schematic drawing of a STT-MRAM cell according to an example embodiment of the present invention;

FIG. 3B depicts a symbolical representation of the STT-MRAM cell shown in FIG. 3A;

FIG. 4 depicts a block diagram illustrating a method of reading a memory device according to various embodiments of the present invention;

FIG. 5 depicts a block diagram illustrating a method of forming a memory device according to various embodiments of the present invention;

FIG. 6 depicts a schematic block diagram showing a system model of LDPC coded STT-MRAM channels in the presence of written-in errors, readback errors and erasures according to various example embodiments of the present invention;

FIG. 7 depicts a schematic block diagram illustrating a fully iterative receiver (detector and decoder) according to a first example embodiment of the present invention;

FIG. 8 depicts a schematic block diagram illustrating a receiver configured to have a simplified configuration (which may be referred to as a one-pass configuration/scheme) according to a second example embodiment of the present invention;

FIG. 9 depicts plots showing the frame-error-rate (FER) performance of the LDPC code under the one-pass scheme according to the second example embodiment compared with various conventional techniques; and

FIG. 10 depicts plots showing the BER/FER performance of the LDPC code under the one-pass scheme compared with various conventional techniques.

### DETAILED DESCRIPTION

Various embodiments of the present invention provide a memory device with soft-decision decoding, and more particularly, a memory device with soft-decision decoding that takes into account (e.g., factoring in) one or more types of errors which may be encountered in the memory device. Various embodiments also provide a corresponding method of reading the memory device and a corresponding method of forming the memory device. In various embodiments, the memory device may be any type of memory device as long as the memory device comprises a memory cell configured to store an input data bit written thereto by being at a particular or predefined state that corresponds to or is representative of a particular or predefined value of the input data bit written thereto. For example, a first state of the memory cell may correspond to logic ‘1’ and a second state of the memory cell may correspond to logic ‘0’, or vice versa.

As mentioned in the background, the reliability of the data recovered from a memory device may be affected by various factors (i.e., various types of errors), including write errors (or may also be referred to herein as written-in errors), parametric errors (or may also be referred to herein as readback errors), and read errors (or may also be referred to herein as read failures, including erasures for example). For example, for a STT-MRAM cell, write errors may be due to variations in the switching current distributions of the magnetic tunneling junction (MTJ) of the memory cell and/or insufficient write current caused by variations of an n-channel metal oxide semiconductor (nMOS) transistor; parametric errors may be due to variations of the MTJ resistances resulting from statistical parametric inconsistencies (e.g., inconsistencies in tunneling oxide thickness and cross-section area of the memory cells in the STT-MRAM device); and read errors may be due to read disturbances, memory sensing inaccuracies, and/or faulty or non-working memory cells (e.g., dead cells which failed during fabrication or for which the breakdown (BD) voltage was exceeded), and so on.

In various embodiments, a memory device with soft-decision decoding is provided that takes into account (e.g., factors in) one or more types of errors which may be encountered in the memory device, and preferably, the parametric errors as well as the write errors and/or the read errors. As will be described later below with reference to example simulations performed according to example embodiments of the present invention, one or more aspects of the memory device according to various embodiments of the present invention is advantageously improved over conventional memory devices, such as an improved error rate performance of the soft-decision decoding over conventional hard-decision or soft-decision decoding.

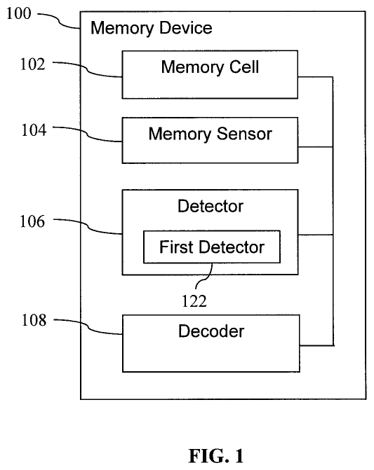

FIG. 1 depicts a schematic block diagram of a memory device 100 according to various embodiments of the present invention. The memory device 100 comprises a memory cell 102 configured to store an input data bit written thereto; a memory sensor 104 configured to sense a parameter associated with a state of the memory cell 102; a detector 106 configured to determine, based on the parameter sensed from the memory cell 102, a first soft information indicating the likelihood that the input data bit written to the memory cell 102 is a predefined value; and a decoder 108 configured to generate an output data bit of the memory cell 102 based on the first soft information. In particular, the detector 106 comprises a first detector 122 configured to determine the first soft information based on a second soft information indicating the likelihood that the state of the memory cell 102 corresponds to a value of the input data bit written to the memory cell 102.

In various embodiments, the input data bit may have a predefined value of either logic ‘1’ or logic ‘0’ only, i.e., a binary data bit. For example, according to various embodiments, the first soft information received by the decoder 108 for generating the output data bit of the memory cell 102 (the output data bit constituting the data bit determined by the decoder 108 to be retrieved from the memory cell 102) is advantageously determined based on a second soft information indicating the likelihood that the state of the memory cell 102 corresponds to a value of the input data bit written to the memory cell 102. For example, if a first state (e.g., a high resistance state) of the memory cell 102 is predefined to correspond to logic ‘1’ and a second state (e.g., a low resistance state) of the memory cell 102 is predefined to correspond to logic ‘0’, then the state of the memory cell 102 should be at the first state or the second state if the input data bit written thereto has a value of logic ‘1’ or logic ‘0’, respectively (that is, the state of the memory cell 102 corresponds to the input data bit written thereto or the input data bit is correctly written to the memory cell 102). However, as mentioned above, due to write errors, the state of the memory cell 102 may not actually correspond to the input data bit written thereto (e.g., the memory cell 102 is at a second state (e.g., a low resistance state) when the input data bit written thereto has a value of logic ‘1’).

Accordingly, possible write error when the input data bit is written to the memory cell 102 is advantageously considered or taken into account in the first soft information based on which the decoder 108 generates the output data bit of the memory cell 102. In this regard, as mentioned hereinbefore and as will be described further later according to example embodiments of the present invention, taking into account possible write error advantageously improves the performance of the memory device, such as but not limited to, an improvement in the error rate performance of the soft-decision decoding over conventional hard-decision or soft-decision decoding which fails to take into account such a possible write error associated with the memory cell.

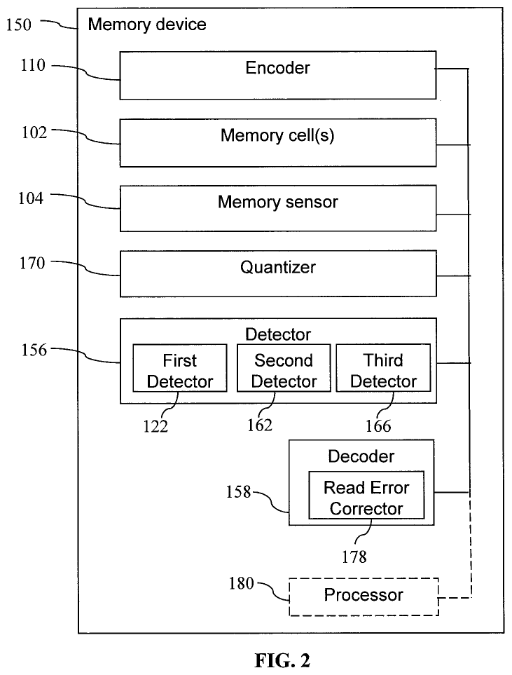

FIG. 2 depicts a schematic block diagram of a memory device 150 according to various embodiments of the present invention, which is the same or similar as the memory device 100 shown in FIG. 1, except that the memory device 150 comprises a number of additional modules or components according to various embodiments of the present invention as will be described hereinafter.

In various embodiments, in the memory device 150, a detector 156 is provided which further comprises a second detector 162 (i.e., in addition to the first detector 122 as described hereinbefore) configured to determine the second soft information based on the parameter sensed from the memory cell 102. Accordingly, possible parametric error associated with the memory cell 102 is advantageously considered or taken into account in the second soft information based on which the first detector 122 determines the first soft information. In this regard, additionally taking into account (e.g., factoring in) possible parametric error associated with the memory cell 102 has been found to further improve the performance (e.g., the error rate performance) of the memory device 150.

It is to be noted that the same reference numerals are applied to the same or similar features or elements throughout the drawings, and the description of the same or similar features or elements may thus be omitted or simplified for the sake of clarity and conciseness.

In various embodiments, the first detector 122 is configured to determine the first soft information based on a log-likelihood ratio of the input data bit based on the second soft information, and the second detector 162 is configured to determine the second soft information based on a log-likelihood ratio of the state of the memory cell 102 based on the parameter sensed from the memory cell 102.

In various embodiments, the likelihood of the input data bit being correctly written into the memory cell 102 is represented (e.g., modelled) by a binary symmetrical channel (BSC), whereby the input data bit is an input to the BSC and the state of the memory cell 102 is an output from the BSC. Therefore, for example, the second detector 162 may be configured to determine the second soft information based on a log-likelihood ratio of the state of the memory cell 102 as output from the BSC channel based on the parameter sensed from the memory cell 102. Further details of the BSC in modelling the possible write error associated with the memory cell 102 will be described later below according to example embodiments of the present invention.

In various embodiments, the log-likelihood ratio of the state of the memory cell based on the parameter sensed from the memory cell 102 may be determined based on probability distributions of the parameter (e.g., MTJ resistances) associated with the memory cell 102, such as, a probability density function (PDF) of the MTJ resistances. Therefore, for example, the second detector 162 may be configured to determine the log-likelihood ratio of the state of the memory cell 102 based on the parameter sensed from the memory cell 102 based on the probability distributions of the parameter to determine the second soft information. In other words, the parametric errors may be represented (e.g., modelled) by the probability distributions of the parameter. Further details of the probability distributions of the parameter in modelling the possible parametric error associated with the memory cell 102 will be described later below according to example embodiments of the present invention.

In various embodiments, the memory device 150 further comprises a quantizer 170 configured to convert the parameter sensed from the memory cell 102 into a corresponding one of a plurality of quantization levels to produce a quantized parameter. In this regard, the detector 156 is configured to determine the first soft information based on the quantized parameter.

In various embodiments, the second detector 162 is further configured to determine the second soft information based on the first soft information fed back from the first detector 122, and the first detector 122 is further configured to determine the first soft information based on a soft information of the output data bit fed back from the decoder 158.

In various embodiments, the detector 156 further comprises a third detector 166 configured to detect a read error of the memory cell 102 based on the parameter sensed from the memory cell 102 and to flag a corresponding data bit position as being affected by the read error if the read error of the memory cell 102 is detected. In this regard, the third detector 166 advantageously takes into account (e.g., factors in) possible read error (e.g., read failures caused by memory sensing failures or non-working cells) to further improve the performance (e.g., error rate performance) of the memory device 150.

In various embodiments, the memory device 150 comprises a plurality of memory cells 102 configured to store input data bits of an input codeword written thereto, respectively, and the decoder 158 comprises a read error corrector 178 configured to receive a plurality of the first soft information determined (by the detector 156) with respect to the input data bits of the input codeword and to correct at least one of the plurality of the first soft information if the at least one first soft information corresponds to at least one data bit position flagged as being affected by the read error.

In various embodiments, the read error corrector 178 is configured to correct the at least one first soft information based on, at a check node associated with a set of data bit positions in which only one data bit position thereof has been flagged as being affected by the read error, determining a new first soft information for replacing the first soft information corresponding to said one data bit position based on one or more bit-to-check inputs from respective one or more bit nodes to the check node. In this regard, the respective one or more bit nodes corresponding to one or more data bit positions of the set of data bit positions not flagged as being affected by the read error. Accordingly, the first soft information at data bit position(s) which have been flagged as being affected by the read error is advantageously recovered or corrected, and a result, further improving the performance (e.g., error rate performance) of the memory device 150.

In various embodiments, the memory device 150 further comprises an encoder 110 configured to encode an input data into an input codeword comprising input data bits (or may also be referred to as input code bits) to be written to the plurality of memory cells 102.

In various embodiments, the encoder 110 is a low-density parity-check (LDPC) encoder and the decoder 158 is a low-density parity-check (LDPC) decoder, and thus, the input codeword is a low-density parity-check (LDPC) codeword. However, it will appreciated by a person skilled in the art that the present invention is not limited to LDPC codewords, and other ECC coding schemes (e.g., RS codes, BCH codes, or turbo codes) may be used as desired or as appropriate.

It will be appreciated by a person skilled in the art that term “memory device” may be interchangably referred to as “memory” or “memory cell arrangement”.

In various embodiments, the memory device 100/150 may be a non-volatile memory device. For example, the memory device 100/150 may also be but are not limited to resistive random-access memory (RRAM) (such as, for example, a phase change memory random-access memory (PCRAM) or conductive bridging random-access memory (CBRAM)) or magnetoresistive random-access memory (MRAM) or redox-based resistive switching memory.

In various embodiments, the memory device 100/150 may be a STT-MRAM device. The memory cell 102 or each of the plurality of memory cells 102 may thus be a STT-MRAM cell, which is a kind of resistive memory cell, that can be switched between two or more states exhibiting different electrical resistance values. In various embodiments, the state of each of the plurality of memory cells 102 may be one of a high resistance state, a low resistance state, and a faulty state, and each of the input data bits has a predefined value of logic ‘1’ or logic ‘0’.

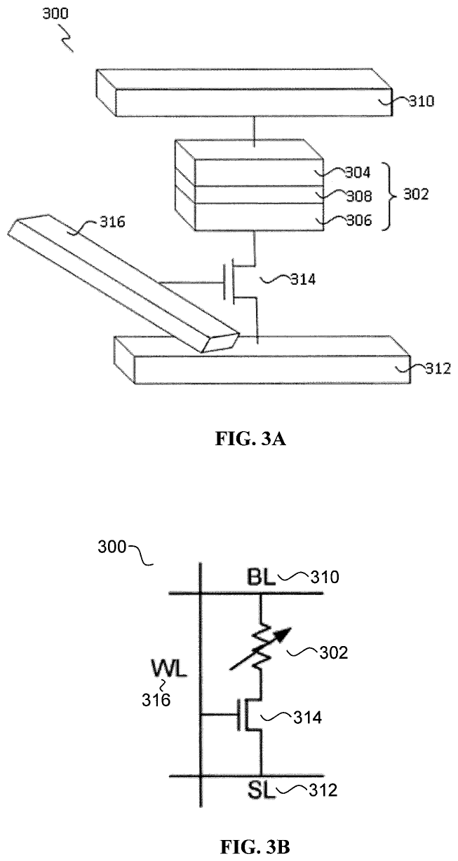

STT-MRAM may be considered as a promising candidate for the next generation of non-volatile memory as it possesses the advantages of scalability, high endurance, high speed and low energy consumption. FIG. 3A shows a schematic drawing of a STT-MRAM cell 300 according to an example embodiment of the present invention. For example, the memory cell 102 of FIGS. 1 and 2 may be configured as the STT-MRAM cell 300 as shown in FIG. 3A. In the example embodiment, the STT-MRAM cell 300 may include a MTJ 302 which comprises a ferromagnetic free layer (FL) 304 and a ferromagnetic reference layer (RL) 306, sandwiching a thin barrier spacer 308. The FL 304 of the MJT 302 may be coupled to a bit line (BL) 310 and the RL 306 of the MJT 302 may be coupled to a source line (SL) 312 via a switching transistor 314 controlled by a word line (WL) 316. Symbolically, the STT-MRAM cell 300 may be represented as shown in FIG. 3B.

The STT-MRAM cell 300 may operate in one of two kinds of schemes, namely, in-plane or perpendicular. The differences lie on the directions of the magnetization direction of the FL 304 and RL 306. For the in-plane STT-MRAM cell, the magnetizations of the FL 304 and RL 306 are lying along the in-plane direction. For the perpendicular STT-MRAM cell, the magnetizations of the FL 304 and RL 306 are lying along the out-of-plane direction. When the magnetizations of the FL 304 and RL 306 are in parallel (P) directions, the magnetoresistance of the STT-MRAM cell is of a low resistance state due to tunneling magnetoresistance effect. On the other hand, the magnetoresistance is of a high resistance state when both the FL 304 and RL 306 are in an anti-parallel (AP) configuration. The switching of the magnetization direction of the FL 304 may occur due to the spin transfer torque effect, having an electrical current flowing through the MTJ device. For example, the direction of the magnetization switching may be controlled by the direction of the electrical current flow.

In various embodiments, the memory sensor 104 may be a circuit that senses or measures a parameter (e.g., MTJ resistances) associated with a state of the memory cell 102 (e.g. a low resistance state or a high resistance state). For example, the parameter may be in an analogue form in terms of voltage, current, or resistance.

In various embodiments, sensing a parameter (or reading out a parameter) may generally refer to a read operation being performed, which is an operation where the parameter associated with the state of the memory cell 102 storing an input data bit (e.g., logic ‘1’ or ‘0’) is “measured”, “obtained” or “determined”. Such a read operation is well known in the art and thus need not be described in detail herein.

In various embodiments, storing an input data bit may generally refer to an input data bit that has been written to the memory cell 102 via a write operation and retained therein. For example, in the context of the STT-MRAM cell 300, storing an input data bit may relate to configuring the state of the memory cell 300, such as, configuring the relative magnetization direction of the FL 304 and RL 306 to configure the resistance of the MTJ. For example, the FL 304 and RL 306 may be configured to have the same magnetization directions so as to be in a low resistance state to store a logic ‘0’ input data bit, or the FL 304 and RL 306 may be configured to have opposite magnetization directions so as to be in a high resistance state to store a logic ‘0’ input data bit.

In various embodiments, soft information may be represented in various ways, for example, may relate to probability and/or may be represented by a log likelihood ratio (LLR).

In various embodiments, it will be appreciated by a person skilled in the art that various modules or components of the memory device 100/150 described herein (e.g., the detector 106/156 and the decoder 108/158) may be hardware module(s) (e.g., circuit(s)) being functional hardware unit(s) designed to perform the required functions/operations or software module(s) realized by computer program(s) or set(s) of instructions executable by at least one computer processor 180 to perform the required functions/operations. It will also be appreciated that a combination of hardware and software modules may be implemented. In the case of software modules, the detector 106/156 and the decoder 108/158 may be stored in one or more computer-readable storage mediums (e.g., memory) accessible by the computer processor 180 for the computer processor 180 to execute the software modules to perform the required or desired functions. For example, the computer-readable storage medium may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In various embodiments, a “circuit” may be understood as any kind of logic implementing entity, which may be a special purpose circuitry or a processor executing software stored in a memory, firmware, or any combination thereof. Thus, in an embodiment, a “circuit” may be a hard-wired logic circuit or a programmable logic circuit such as a programmable processor, e.g., a microprocessor (e.g., a Complex Instruction Set Computer (CISC) processor or a Reduced Instruction Set Computer (RISC) processor). A “circuit” may also be a processor executing software, e.g., any kind of computer program, e.g., a computer program using a virtual machine code, e.g., Java. Any other kind of implementation of the respective functions which will be described in more detail below may also be understood as a “circuit” in accordance with various alternative embodiments. Similarly, a “module” may be a portion of a system/device according to various embodiments in the present invention and may encompass a “circuit” as above, or may be understood to be any kind of a logic-implementing entity therefrom.

Some portions of the present disclosure are explicitly or implicitly presented in terms of algorithms and functional or symbolic representations of operations on data within a computer memory. These algorithmic descriptions and functional or symbolic representations are the means used by those skilled in the data processing arts to convey most effectively the substance of their work to others skilled in the art. An algorithm is here, and generally, conceived to be a self-consistent sequence of steps leading to a desired result. The steps are those requiring physical manipulations of physical quantities, such as electrical, magnetic or optical signals capable of being stored, transferred, combined, compared, and otherwise manipulated.

Unless specifically stated otherwise or the context clearly indicates otherwise, and as apparent from the following, it will be appreciated that throughout the present specification, discussions utilizing terms such as “determining”, “generating”, “detecting”, “correcting” or the like, refer to the actions and processes of a computer system, or similar electronic device, that manipulates and transforms data represented as physical quantities within the computer system into other data similarly represented as physical quantities within the computer system or other information storage, transmission or display devices.

In addition, the present specification also at least implicitly discloses a computer program or software/functional module, in that it would be apparent to the person skilled in the art that various individual steps of the methods described herein may be put into effect by computer code. The computer program is not intended to be limited to any particular programming language and implementation thereof. It will be appreciated that a variety of programming languages and coding thereof may be used to implement the teachings of the disclosure contained herein. Moreover, the computer program is not intended to be limited to any particular control flow. There are many other variants of the computer program, which can use different control flows without departing from the spirit or scope of the invention.

The software or functional modules described herein may also be implemented as hardware modules. More particularly, in the hardware sense, a module is a functional hardware unit designed for use with other components or modules. For example, a module may be implemented using discrete electronic components, or it can form a portion of an entire electronic circuit such as an Application Specific Integrated Circuit (ASIC). Numerous other possibilities exist. Those skilled in the art will appreciate that the software or functional module(s) described herein can also be implemented as a combination of hardware and software modules.

It will be appreciated by a person skilled in the art that the terminologies used herein are for the purpose of describing various embodiments only and are not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

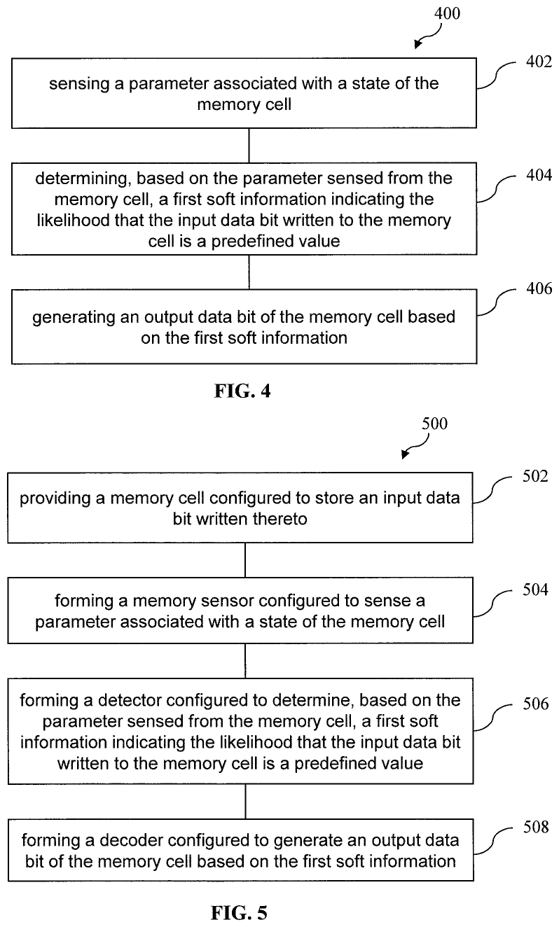

FIG. 4 depicts a block diagram illustrating a method 400 of reading a memory device according to various embodiments of the present invention, such as the memory device 100/150 as illustrated in FIGS. 1 and 2. As described hereinbefore, the memory device comprising a memory cell 102 configured to store an input data bit written thereto. The method 400 comprises a step 402 of sensing a parameter associated with a state of the memory cell 102; a step 404 of determining, based on the parameter sensed from the memory cell 102, a first soft information indicating the likelihood that the input data bit written to the memory cell 102 is a predefined value; and a step 406 of generating an output data bit of the memory cell 102 based on the first soft information. In particular, the step 404 of determining a first soft information comprises determining the first soft information based on a second soft information indicating the likelihood that the state of the memory cell 102 corresponds to a value of the input data bit written to the memory cell 102.

In various embodiments, the method 400 of reading a memory device corresponds to the memory device 100/150 as described hereinbefore with reference to FIGS. 1 and 2, therefore, various steps of the method 400 may correspond to various modules or components of the memory device 100/150 described in hereinbefore according to various embodiments of the present invention, and thus need not be repeated with respect to the method 400 for clarity and conciseness. In other words, various embodiments described herein in context of the devices are analogously valid for the respective methods, and vice versa. For example and without limitation, the step 402 of sensing a parameter may correspond to the function(s) or operation(s) configured to be performed by the memory sensor 104; the step 404 of determining a first soft information may correspond to the function(s)/operation(s) configured to be performed by the detector 106/156; and the step 406 of generating an output data bit of the memory cell 102 may correspond to the function(s)/operation(s) configured to be performed by the decoder 108/158.

FIG. 5 depicts a block diagram illustrating a method 500 of forming a memory device according to various embodiments of the present invention, such as the memory device 100/150 as illustrated in FIGS. 1 and 2. The method comprises a step 502 of providing a memory cell 102 configured to store an input data bit written thereto; a step 504 of forming a memory sensor 104 configured to sense a parameter associated with a state of the memory cell; a step 506 of forming a detector 106 configured to determine, based on the parameter sensed from the memory cell 102, a first soft information indicating the likelihood that the input data bit written to the memory cell 102 is a predefined value; and a step 508 of forming a decoder 108 configured to generate an output data bit of the memory cell 102 based on the first soft information. In particular, the detector 108 comprises a first detector 122 configured to determine the first soft information based on a second soft information indicating the likelihood that the state of the memory cell 102 corresponds to a value of the input data bit written to the memory cell 102.

In order that the present invention may be readily understood and put into practical effect, various example embodiments of the present invention will be described hereinafter by way of examples only and not limitations. It will be appreciated by a person skilled in the art that the present invention may, however, be embodied in various different forms or configurations and should not be construed as limited to the example embodiments set forth hereinafter. Rather, these example embodiments are provided so that this disclosure will be thorough and complete, and will fully convey the scope of the present invention to those skilled in the art.

Various example embodiments of the present invention provide coding and signal processing for non-volatile memories (NVM), and in particular, for STT-MRAM. For example, various example embodiments may provide information theory based design of LDPC-coded channel for STT-MRAM.

As mentioned hereinbefore, memory channels (e.g., STT-MRAM channels) may be subjected write errors, readback errors (e.g., parametric errors) and read errors (e.g., erasures), that respectively result from, for example, insufficient write current, variations in resistance distributions amongst the memory cells, and presence of dead cells (e.g., open or short circuited) which failed during manufacturing or for which the BD voltage was exceeded. In this regard, various example embodiments of the present invention provide an improved detection and decoding architecture (or may simply be referred to herein as “receiver” or “receiver structure”) (and associated technique/method) that advantageously takes into account these types of errors. In various example embodiments, the write errors may be modelled by a BSC (e.g., crossover (flipped bit) with probability p), readback errors may be modelled by a resistance distribution, and dead cells may be modelled by setting resistance to zero or infinity (∞). In contrast, for example, conventional detection and decoding techniques on LDPC codes for STT-MRAM and flash memories do not consider the effect of written errors and erasures.

Various example embodiments provide a soft-decision detector and decoder (receiver) and the corresponding detection and decoding technique for LDPC codes over STT-MRAM in the presence of written-in errors (e.g., corresponding to the “write errors” as described hereinbefore) and erasures (e.g., corresponding to the “read errors” as described hereinbefore), in addition to the readback errors (e.g., corresponding to the “parametric errors” as described hereinbefore). In various example embodiments, a soft-decision BSC is provided to correct or factor in the written-in errors and an erasure-based LDPC decoder is provided for recovering erased bits. For example, the written-in errors are modeled as the output of the soft-decision BSC, while random erasures are inserted to model read failures due to, for example, non-working cells or memory sensing errors.

For illustration purpose and without limitations, two receiver structures (and associated detection and decoding techniques) are provided to mitigate the effect of written-in errors and erasures according to various example embodiments of the present invention.

According to a first example embodiment, a fully iterative receiver is provided that comprises a soft channel detector (e.g., soft-output channel log-likelihood ratio (LLR) generator) (e.g., corresponding to the “second detector” 162 as described hereinbefore according to various embodiments of the present invention), a soft-input mapper (e.g., soft-input BSC mapper) (e.g., corresponding to the “first detector” 122 as described hereinbefore according to various embodiments of the present invention), and an erasure-based soft-decision LDPC decoder (e.g., corresponding to the “decoder” 158 including the “read error corrector” 178 as described hereinbefore according to various embodiments of the present invention), where feedback loops are used to pass extrinsic information between these components.

According to a second example embodiment, it is noted that the fully iterative receiver may have high computational complexity and requires iterations to be performed in order to obtain the decisions/outputs. In this regard, in the second example embodiment, to provide a faster read access time, a simplified one-pass technique/scheme is provided that removes feedback loops in the fully iterative receiver. In this regard, it has been surprisingly found that the one-pass receiver results in a significant improvement in the read access time while only resulting in a slight performance degradation in terms of error rate. As will be described later below with reference to example simulations performed, the simulation results show that the LDPC code with the one-pass scheme achieves a much better performance as compared with the state-of-art BCH codes based on hard-decision decoding (HDD) when both written-in errors and erasures are present in STT-MRAM.

For better understanding of the present invention and without limitation or loss of generality, the memory device 100/150 will now be described further with respect to a STT-MRAM device according to various example embodiments of the present invention. However, as mentioned hereinbefore, it will be appreciated by a person skilled in the art that the memory device 100/150 is not limited to a STT-MRAM device may be other types of memory device as desired or as appropriate.

### System/Device Model

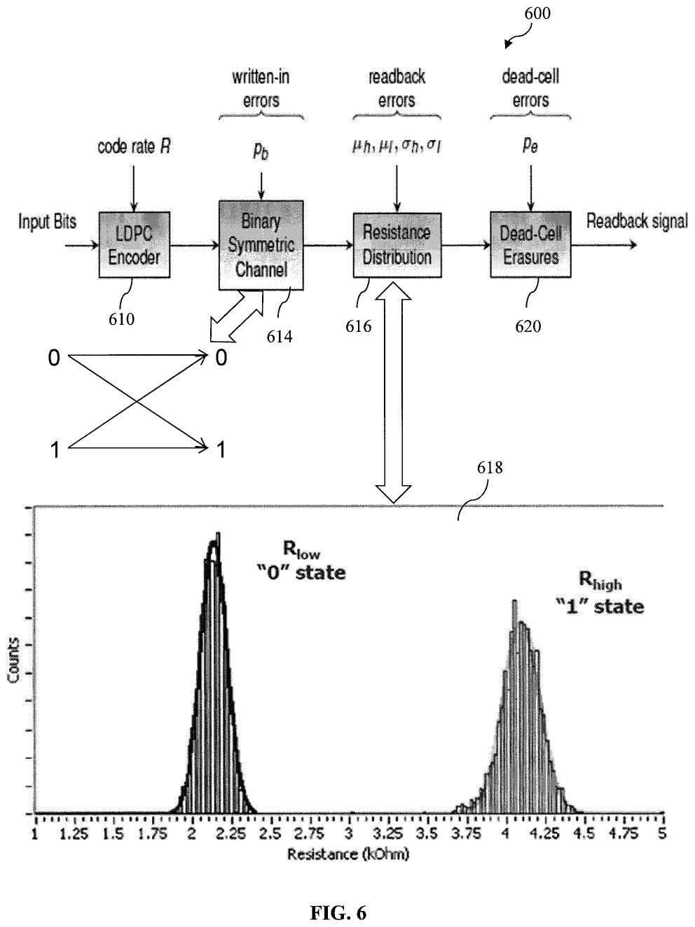

FIG. 6 depicts a schematic block diagram showing a system model 600 of LDPC coded STT-MRAM channels in the presence of written-in errors, readback errors and erasures according to various example embodiments of the present invention. In the system model 600, the written-in errors are modelled as the output of a BSC 614, whose crossover probability is set to the write error probability p_{b}. Hence, the LDPC code bits encoded by the LDPC encoder 610 are written into STT-MRAM cells correctly with a probability 1−p_{b}, that is, P(\hat{b}ₖ=b)=1−p_{b}, k=1, . . . , N, where \hat{b} denotes the LDPC codeword of length N (e.g., corresponding to the “input data bit(s)” as described hereinbefore), and \hat{b} denotes the BSC output (e.g., corresponding to the “state of the memory cell” as described hereinbefore according to various embodiments of the present invention). Equivalently, the BSC output may be expressed as:

\hat{b}ₖ=bₖ⊕xₖ, (Equation 1)

where ⊕ denotes the Boolean XOR operation, xₖ is an auxiliary binary random variable (r.v.) independent of bₖ with probability P(xₖ=1)=p_{b} and P(xₖ=0)=1−p_{b}. The BSC output \hat{b} is transmitted over STT-MRAM channels whose probability density functions (pdf) of MTJ resistances are given by P(yₖ|\hat{b}ₖ=i), i=0 and 1, respectively, where yₖ denotes the analogue memory cell resistance value.

Without loss of generality, the low resistance state is associated with p(\hat{b}ₖ=0) and the high resistance state associated with p(\hat{b}ₖ=1). In an example STT-MRAM device, an n-bit quantizer (e.g., corresponding to the “quantizer” 170 as described hereinbefore according to various embodiments of the present invention) with L=2ⁿ quantization levels is used to map yₖ into quantized readback signals \tilde{y}ₖ. Let t₀, t₁, . . . , t_{L} denote the boundaries of the quantization intervals with to t₀=−∞ and t_{L}=∞, and Tⱼ=(aⱼ, aⱼ₊₁], j=0, . . . , L−1, denotes the jth quantization interval. The transition probability, which is the probability of the unquantized value yₖ falling into the jth quantization interval Tⱼ, may be given by:

$$\begin{matrix}{P}_{ij} = P ( {y}_{k} ∈ {T}_{j} \vert {\hat{b}}_{k} = i ) \\ = {\int }_{{T}_{j}}^{ } P ( {y}_{k} \vert {\hat{b}}_{k} = i ) {dy}_{k} \end{matrix} \qquad ( Equation 2 )$$

For example, as described in E. Chen, D. Apalkov, Z. Diao, et al., “Advances and future prospects of spin-transfer torque random access memory”, IEEE Transactions on Magnetics, vol. 46, no. 6, pages 1873-1878, June 2010 (herein referred to as the Chen reference), the contents of which are hereby incorporated by reference in their entirety for all purposes, the probability distributions (yₖ|\hat{b}ₖ=i) with i=0 and 1, which correspond to the MTJ low and high resistance state, respectively, can be well approximated by Gaussian distributions. That is, the resistance distributions 616 may be, but is not limited to be, based on the Gaussian distribution 618 as illustrated in FIG. 6 by way of example only. As a non-limiting example, for the static resistance of a 14 Kb STT-MRAM testing chip integrated with a 90 nm CMOS, their mean values are μ₀=2.0625 kΩ and μ₁=4.1250 kΩ while the standard deviations are given by σ₀=0.0825 kΩ and σ₁=0.1238 kΩ. Thus, the tunnelling magnetoresistance (TMR) is 100% with σ₁=1.5σ₀ and σ₁/μ₁=0.750σ₀/μ₀. It is noted that in general, the relationship between the relative spreads of the two resistance states (i.e., σ₁/μ₁ versus σ₀/μ₀) does not change significantly in the lithography process. In various embodiments, the resistance distributions 616 are further widened by increasing the value of σ₀/μ₀ to account for resistance variations in practical systems.

In addition to written-in errors, the STT-MRAM may also be subjected to read failures caused by, for example, memory sensing failures and non-working cells (faulty cells) arising from the imperfections of memory fabrication processes. In various example embodiments, to characterize the read failures, a probabilistic model 620 is used to introduce erasures to the readback signal with an erasure probability pₑ.

### Soft Detection/Decoding Schemes/Techniques

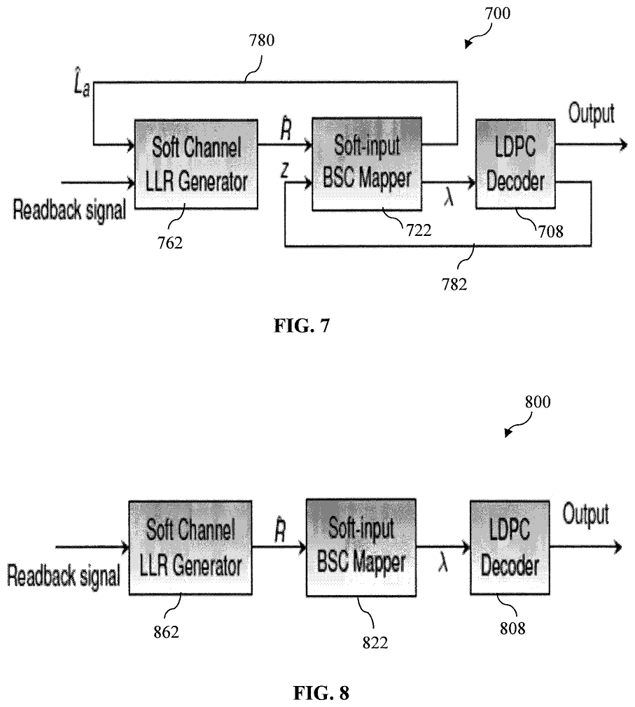

FIG. 7 depicts a schematic block diagram illustrating a fully iterative receiver (detector and decoder) 700 according to a first example embodiment of the present invention. The receiver 700 comprises three modules or components, namely, a channel detector (e.g., a soft-output channel LLR generator) 762 (e.g., corresponding to the “second detector” 162 as described hereinbefore according to various embodiments of the present invention), a soft-input mapper (e.g., soft-input BSC mapper) 722 (e.g., corresponding to the “first detector” 122 as described hereinbefore according to various embodiments of the present invention), and an erasure-based soft-decision LDPC decoder 708 (e.g., corresponding to the “decoder” 158 including the “read error corrector” 178 as described hereinbefore according to various embodiments of the present invention).

### Channel Detector (Soft-Output Channel LLR Generator) 762

In various example embodiments, by way of an example only and without limitation, the soft-output channel LLR generator 762 is configured to compute the a posteriori probability (APP) LLR of the BSC output \hat{b} based on the quantized readback signal \tilde{y}ₖ as:

$$\begin{matrix}{\hat{R}}_{k} = log \frac{P ( {\hat{b}}_{k} = 1 \vert {\tilde{y}}_{k} )}{P ( {\hat{b}}_{k} = 0 \vert {\tilde{y}}_{k} )} \\ = log \frac{P ( {\tilde{y}}_{k} \vert {\hat{b}}_{k} = 1 )}{P ( {\tilde{y}}_{k} \vert {\hat{b}}_{k} = 0 )} + log \frac{P ( {\hat{b}}_{k} = 1 )}{P ( {\hat{b}}_{k} = 0 )} \\ = {L}_{ch , k} + {\hat{L}}_{a , k}\end{matrix} \qquad ( Equation 3 )$$

where the subscript ch denotes the LLR based on the readback signal from the channel, the subscript a denotes the a priori information of \hat{b}, and k denotes the kth bit, k=1, . . . , N. Assuming that \tilde{y}ₖ falls into the jth quantization interval, j=0, . . . , L−1, L_{ch,k} can be represented by:

$${L}_{ch , k} = log \frac{{P}_{1 , j}}{{P}_{o , j}} \qquad ( Equation 4 )$$

where the transition probabilities P_{i,j}, i=0 and 1, are computed using Equation (2) based on the distributions of MTJ resistance states and the quantization parameters.

### Soft-Input Mapper (Soft-Input BSC Mapper) 722

In various example embodiments, for STT-MRAM with written-in errors, the BSC is used to introduce flipping to LDPC code bits with a crossover probability p_{b}. Since the BSC is concatenated with an outer LDPC decoder, the BSC detector (Soft-Input BSC Mapper) 722 is configured to deliver real-value soft information rather than binary hard information to the soft-decision LDPC decoder as the input. For example, the conventional BSC detector disclosed in W. E. Ryan, “An Introduction to LDPC Codes”, CRC Handbook for Coding and Signal Processing for Recording Systems, Ed., B. Vasic and E. Kurtas, CRC Press, 2004 (hereinafter referred to as the Ryan reference), makes hard decisions \hat{b}_{hd} of the BSC output \hat{b} based on the readback signals y and produces the LLR of BSC input bits b (i.e., LDPC code bits) as:

$$\begin{matrix}{L}_{k} = log \frac{P ( {b}_{k} = 1 \vert {y}_{k} )}{P ( {b}_{k} = 0 \vert {y}_{k} )} \\ = \{ \begin{matrix}log \frac{{p}_{b}}{1 - {p}_{b}} {\hat{b}}_{hd , k} = 0 \\ log \frac{1 - {p}_{b}}{{p}_{b}} {\hat{b}}_{hd , k} = 1\end{matrix}\end{matrix} \qquad ( Equation 5 )$$

where \hat{b}_{hd,k}=0 when yₖ<yₜₕ, \hat{b}_{hd,k}=1 otherwise, and yₜₕ is the threshold value of y defined by the resistance distributions. From Equation (5), it can be deduced that the conventional BSC detector is a hard-input mapping device that converts binary hard information (logic 0's or 1's) at the input to the constant LLR values of ±log(p_{b}/(1−p_{b})), respectively. Therefore, it does not differentiate between the reliabilities of readback signals, which inevitably leads to serious performance degradation when used with LDPC codes.

In contrast, in various example embodiments of the present invention, a soft-input BSC mapper 722 is provided and configured to directly accept the soft information \hat{R}ₖ (e.g., corresponding to the “second soft information” as described hereinbefore according to various embodiments of the present invention) as provided by the channel LLR generator 762. More specifically, the soft-input BSC mapper 722 is configured to produce the APP LLR (e.g., corresponding to the “first soft information” as described hereinbefore according to various embodiments of the present invention) of LDPC code bits b as:

$$\begin{matrix}{L}_{k} = log \frac{P ( {b}_{k} = 1 \vert {\hat{R}}_{k} )}{P ( {b}_{k} = 0 \vert {\hat{R}}_{k} )} \\ = log \frac{P ( {b}_{k} = 1 , {\hat{b}}_{k} = 1 \vert {\hat{R}}_{k} ) + P ( {b}_{k} = 1 , {\hat{b}}_{k} = 0 \vert {\hat{R}}_{k} )}{P ( {b}_{k} = 0 , {\hat{b}}_{k} = 1 \vert {\hat{R}}_{k} ) + P ( {b}_{k} = 0 , {\hat{b}}_{k} = 0 \vert {\hat{R}}_{k} )}\end{matrix} \qquad ( Equation 6 )$$

It can be understood by a person skilled in the art that after some mathematical derivations, Lₖ can be expressed as:

$${L}_{k} = log \frac{A + B exp ( {\hat{R}}_{k} )}{C + D exp ( {\hat{R}}_{k} )} \qquad ( Equation 7 )$$

where the parameters A, B, C, and D are given by:

$$A = \frac{{p}_{b} exp ( {Z}_{k} )}{{p}_{b} exp ( {Z}_{k} ) + ( 1 - {p}_{b} )} \\ B = \frac{( 1 - {p}_{b} ) exp ( {Z}_{k} )}{( 1 - {p}_{b} ) exp ( {Z}_{k} ) + {p}_{b}} \\ C = \frac{1 - {p}_{b}}{{p}_{b} exp ( {Z}_{k} ) + ( 1 - {p}_{b} )} \\ D = \frac{{p}_{b}}{( 1 - {p}_{b} ) exp ( {Z}_{k} ) + {p}_{b}} \qquad ( Equation 8 )$$

and Zₖ is the a priori LLR of LDPC code bits b (e.g., corresponding to the “soft information of the output data bit(s)” as described hereinbefore according to various embodiments of the present invention), which may be fed back from the LDPC decoder 708 to the soft-input BSC mapper 722, such as via a second feedback loop 782 as shown in FIG. 7. For the kth bit, the soft input λ (e.g., corresponding to the “first soft information” as described hereinbefore according to various embodiments of the present invention) to the LDPC decoder 708 is obtained as the extrinsic information of the BSC mapper 722:

λₖ=Lₖ−Zₖ (Equation 9)

In addition, the BSC mapper 722 provides the updated soft information of the BSC output \hat{b}, which can be fed back to the channel LLR generator 762 as the a priori information \hat{L}ₐ, such as via a first feedback loop 780 as shown in FIG. 7. In various example embodiments, the information fed back from the LDPC decoder 708 to the BSC mapper 722 is the a priori information of LDPC code bits and, for example, may be used as Zₖ in Equation 8 described hereinbefore; while the information fed back from the BSC mapper 722 to the LLR generator 762 is the a priori information of BSC output \hat{b} and, for example, may be used as \hat{L}ₐ in Equation (3) described hereinbefore.

### Soft-Decision Erasure-Based LDPC Decoder 708

In various example embodiments, the LDPC decoder 708 is based on the sum-product algorithm (SPA) (or its variations), which is a message-passing algorithm performed over the Tanner graph of a LDPC code. The details of the SPA is known in the art and can be found in, for example, the Ryan reference, the contents of which are hereby incorporated by reference in their entirety for all purposes. After several iterations between check nodes and bit nodes, the LDPC decoder 708 produces hard decisions (either logic ‘1’ or ‘0’) and extrinsic information (soft information) of LDPC code bits. For example, the LDPC decoder 708 may use the SPA to produce the soft information of LDPC code bits based on a conventional technique known in the art, such as described in the Ryan reference. The soft information produced may then be fed back to the soft-input BSC mapper 722 and, for example, used in Equation (8) as described hereinbefore to update the soft information of LDPC code bits.

In various example embodiments, when the STT-MRAM device is affected with erasures due to, for example, read failures, the readback signals on erased bit positions are composed of random channel noises and thus have small magnitudes. For example, non-working cells (e.g., dead cells) may result in readback signals with magnitudes which are relatively small, such as close to zero since the readback signals may be made up of random channel noise. In this regard, according to various example embodiments, a threshold detector (e.g., corresponding to the “third detector” 166 as described hereinbefore according to various embodiments of the present invention) is used to detect and mark erasure positions. For example, when the magnitude of the readback signal is smaller than a predetermined threshold, the corresponding data bit position is flagged as an erasure. By way of an example only and without limitation, an exemplary threshold on the readback signal magnitude used in the simulations is 0.05.

The erasure flag for the entire codeword may then passed to the LDPC decoder 708 as a priori information and used in the soft-decision decoding. In various example embodiments, the erasure flags are generated based on the soft information produced by the BSC mapper 722. For example, when the LLR magnitude of a LDPC code bit produced by the BSC mapper 722 is smaller than a predetermined threshold (e.g., 0.05), an erasure for the LDPC code bit is flagged. For example, the erasure flag for a LDPC code bit may have a binary data format, which may take the value of 1 to indicate that the LDPC code bit has been determined to be affected by an erasure, otherwise, the erasure flag may be set to the value of 0. For example, the erasure flags of the entire LDPC codeword is passed to the LDPC decoder 708 and used in the soft-decision decoding. In various example embodiments, the generation of the erasure flags involving the above-described thresholding operation may be incorporated in the LDPC decoder 708.

Various example operations/functions of an erasure-based soft-decision LDPC decoder 708 to recover erased bits for STT-MRAM channels will now be described according to various example embodiments of the present invention. The LDPC decoder 708 may be configured to perform the following steps/operations to recover erased bits for STT-MRAM channels:
1. Set to zeros the initial LLR of LDPC code bits (e.g., corresponding to the “plurality of first soft information” as described hereinbefore according to various embodiments of the present invention) on erased positions as indicated by the erasure flags for the LDPC code bits at the input of the LDPC decoder 708;
2. In the LDPC decoding process, if a check node is connected to only one erased bit (in other words, associated with a set of data bit positions in which only one data bit position thereof has been flagged as being affected by the read error), produce the check-to-bit LLR (e.g., corresponding to the “new first soft information” as described hereinbefore according to various embodiments of the present invention) for the erased bit node based on bit-to-check inputs from the other (i.e., non-erased) bit nodes connected to the check node and flag the erased bit as recovered. In this step, no check-to-bit information is produced for the non-erased bit nodes. For example, the check-to-bit LLR for the erased bit may be produced based on the bit-to-check inputs from the non-erased bit nodes, for example, using the sum-product algorithm (SPA) in a conventional technique which may be known as the check-node processing, such as described in the Ryan reference, and thus need not be described herein.
3. If a check node is connected to two or more erased bits, skip the check node and proceed to a check node where only one bit is affected by the erasure while the other bits participating in the check are either non-erased or recovered. This technique has been found to facilitate the LDPC decoder 708 to recovers all erased bits, provided each check node is connected to at most one erased bit.
4. Repeat the above steps 1 to 3 to recover erased bits in a successive manner until the number of erasures per check node cannot be further reduced.
5. Perform the message passing between bit nodes and check nodes, and at each iteration, produce a hard decision of the LDPC codeword. If the hard decision produced for the LDPC codeword satisfies all syndrome checks, stop the LDPC decoder 708 from decoding the current set of data bits and return the hard decision (data bits) as the output data bits for the current set of data bits.

In various example embodiments, for the decoding iterations, the computational complexity is advantageously reduced by restricting check node operations to bit-to-check inputs with smallest reliabilities.

As described hereinbefore, FIG. 7 shows that the receiver 700 for STT-MRAM channels according to the first example embodiment has a doubly-iterative structure in that the receiver 700 features a first feedback loop 780 between the soft-input BSC mapper 722 and the channel LLR generator 762, and a second feedback loop 782 between the erasure-based LDPC decoder 708 and the soft-input BSC mapper 722. The receiver 700 stops decoding the current set of data bits whenever the LDPC decoder 708 produces a valid codeword that satisfies all syndrome checks and returns the hard decision (data bits) as the output data bits for the current set of data bits.

As also described hereinbefore, the fully iterative receiver as shown in FIG. 7 according to the first example embodiment may be computationally intensive as iterations are required between three components, namely, between the soft-input BSC mapper 722 and the channel LLR generator 762, and between the erasure-based LDPC decoder 708 and the soft-input BSC mapper 722. In this regard, FIG. 8 depicts a schematic block diagram showing a receiver 800 configured to have a simplified configuration according to a second example embodiment, which may be referred to as a one-pass configuration, which eliminates the two feedback loops 780, 782 provided in the receiver 700 according to the first example embodiment. For the one-pass configuration/scheme, the receiver 800 comprises three modules or components, namely, a channel detector (e.g., a soft-output channel LLR generator) 862 (e.g., corresponding to the “second detector” 162 as described hereinbefore according to various embodiments of the present invention), a soft-input mapper (e.g., soft-input BSC mapper) 822 (e.g., corresponding to the “first detector” 122 as described hereinbefore according to various embodiments of the present invention), and a LDPC decoder (e.g., an erasure-based soft-decision LDPC decoder) 708 (e.g., corresponding to the “decoder” 158 including the “read error corrector” 178 as described hereinbefore according to various embodiments of the present invention). In particular, in the receiver 800, the soft-input BSC mapper 822 is configured to produce the APP LLR (e.g., corresponding to the “first soft information” as described hereinbefore according to various embodiments of the present invention) of LDPC code bits solely based on the channel LLR (e.g., corresponding to the “second soft information” as described hereinbefore according to various embodiments of the present invention), that is, without a priori information being fed back from the LDPC decoder 808. By way of an example and without limitation, in various example embodiments, the simplified soft-input BSC mapper 822 may be expressed as:

$${\hat{L}}_{a , k} = \{ \begin{matrix}log \frac{1 - {p}_{b}}{{p}_{b}} + log \frac{( {p}_{b} / ( 1 - {p}_{b} ) + exp ( {\hat{R}}_{k} ) )}{( ( 1 - {p}_{b} ) / {p}_{b} + exp ( {\hat{R}}_{k} ) )} , & {R}_{k} \geq 0 \\ log \frac{{p}_{b}}{1 - {p}_{b}} + log \frac{( ( 1 - {p}_{b} ) / {p}_{b} ) + exp ( - {\hat{R}}_{k} )}{( {p}_{b} / ( 1 - {p}_{b} ) ) + exp ( - {\hat{R}}_{k} )} , & {\hat{R}}_{k} < 0\end{matrix} \qquad ( Equation 10 )$$

According to various example embodiments, it is noted that the conventional hard-input BSC mapper based on Equation (5) may be viewed as a special case of Equation (10) when the input channel LLR \hat{R}ₖ tends to infinity, that is, the hard-input BSC mapper assumes that hard decisions made at the input of the mapper are correct.

In example simulations performed according to various example embodiments, simulation results show that the one-pass configuration can achieve very close error rate performance to the fully iterative configuration/scheme for STT-MRAM channels. In the following, the one-pass configuration will be described further due to its lower implementation complexities, and simulation results are discussed to demonstrate its effectiveness over LDPC coded STT-MRAM channels.

### Simulation Results

In example embodiments, computer simulations were carried out using the STT-MRAM channel as an example to demonstrate the effectiveness of the detection and decoding scheme/technique according to various embodiments in the presence of written-in errors and random erasures. To reduce the decoding latency and coding overhead, a high-rate short-length LDPC code is used in the simulations. The LDPC code was constructed based on the three-dimensional Euclidean Geometry EG(3,2²) over GF(2²). This geometry consists of 64 points and 336 lines, which can be grouped into 21 parallel bundles. The incidence matrix of each parallel bundle is a 16×64 matrix with column weight 1 and row weight 4. By stacking column-wise all 21 incidence matrices, a 336×64 matrix with column weight 21 and row weight 4 can be formed. The null space of the transpose of this matrix gives a (336, 285) LDPC code with rate 0.848 and minimum distance at least 5. It should be noted that the code rate and codeword length of the LDPC code are designed to be close to the (292, 256, 4) BCH code for STT-MRAM channels (according to the Chen reference) to facilitate a fair comparison. The latter is shortened from a (511, 475, 4) BCH code with an error-correcting capability of 4 bit errors for HDD. The number of quantization bits used over the STT-MRAM channel is 4, i.e., 16 quantization intervals.

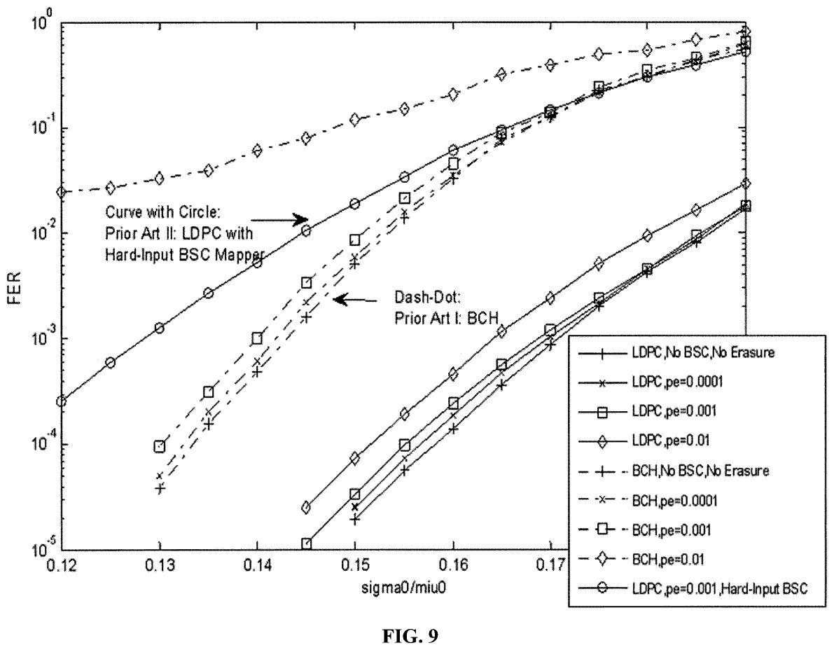

FIG. 9 depict plots showing the frame-error-rate (FER) performance of the LDPC code under the one-pass scheme according to the second example embodiment whereby the BSC crossover probability was set to p_{b}=10⁻⁵, while the erasure probability pₑ was allowed to vary from 10⁻⁴ to 10⁻² to account for different amounts of erasures introduced to the readback signal. For benchmark purposes, the performance of the state-of-art BCH code based on the HDD (herein referred to as “Conventional Technique 1”) is included in FIG. 9. Also included in FIG. 9 is the performance of the LDPC code decoded with the conventional hard-input BSC mapper (herein referred to as “Conventional Technique 2”) replacing the soft-input BSC mapper. Unless specified, the soft-input BSC detector is used to deliver soft information to the erasure-based soft-decision LDPC decoder.

FIG. 9 shows that the LDPC code with the one-pass scheme provides a significant performance gain over the BCH code (Conventional Technique 1) when the STT-MRAM channel suffers from both written-in errors and random erasures. Moreover, the performance gain is shown to increase when a larger amount of erasures is imposed on the channel. When the erasure probability is at pₑ=10⁻⁴, the LDPC code with the one-pass scheme outperforms the BCH code by 2% in terms of the maximum tolerable resistance distribution. The gain is enhanced to 3% when pₑ is increased to 10⁻³. FIG. 9 shows that the BCH code suffers from serious degradation as compared with the benchmark performance when the erasure probability is further increased to pₑ=10⁻². In contrast, the LDPC code with the one-pass scheme operates close to the benchmark performance within 0.5% in terms of the resistance distribution spread and provides much better performance than the BCH code by more than two orders of magnitudes. It is also shown that the LDPC decoder with the conventional hard-input BSC mapper (Conventional Technique 2) fails to work at pₑ=10⁻³ and performs even worse than the BCH code.

Hence, it can be observed that the detecting and decoding scheme/technique with the soft-input BSC mapper and the erasure-based LDPC decoder according to various embodiments of the present invention is able to allow the LDPC code to achieve a notable performance gain over, for example, the BCH code (Conventional Technique 1) in the entire range of simulated resistance distributions.

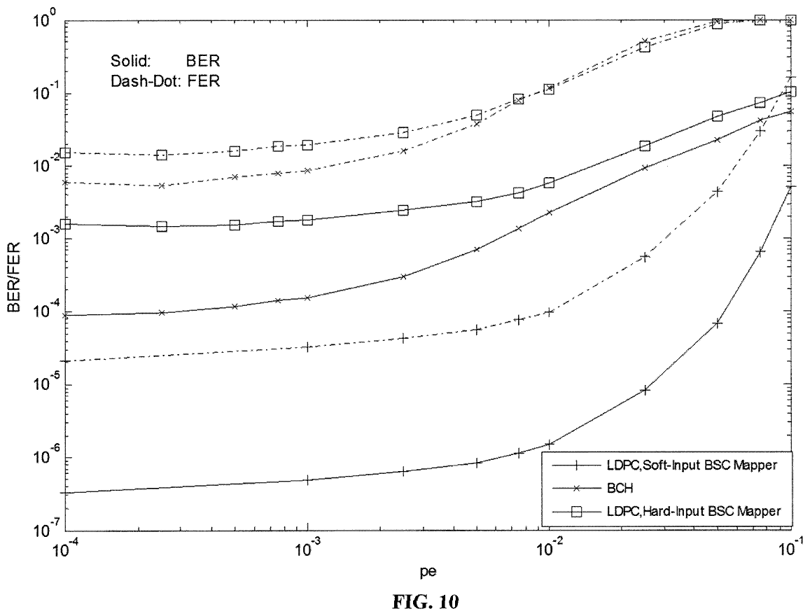

FIG. 10 shows the performance (BER/FER) of the LDPC code with the one-pass scheme and the BCH code when the resistance spread of the lower state is set to σ₀/μ₀=0.15 and the BSC crossover probability is set to p_{b}=10⁻⁵. FIG. 10 shows that the LDPC code with the one-pass scheme achieved a reduction in BER by two orders of magnitudes over the BCH code (Conventional Technique 1) when the erasure probability is pₑ=10⁻⁴. Moreover, the LDPC code with the one-pass scheme achieved the BER of 10⁻⁶ for the specified resistance distribution at pₑ=10⁻², while the BCH code obtains the BER of 10⁻³. FIG. 10 shows that the LDPC code with the one-pass scheme is more tolerable to random erasures over the STT-MRAM channel as compared with the BCH code. Moreover, the performance of the LDPC code with the one-pass scheme varies only slightly when the erasure probability pₑ is less than 10⁻², while the BCH code starts to show severe degradation even when pₑ is greater than 10⁻³. For comparison purposes, the performance of the LDPC code with the conventional hard-input BSC mapper (Conventional Technique 2) is also included in FIG. 10. It is shown that the hard-input BSC mapper does not work effectively for LDPC codes and results in a performance even worse than the BCH code. In contrast, the receiver according to the second example embodiment of the present invention enables the LDPC code to achieve a significant performance gain over the state-of-art BCH code for STT-MRAM channels.

Thus, the above results demonstrate the capability of the detection and decoding scheme/technique according to various embodiments of the present invention, for example, when short-length LDPC codes are used to improve the storage density and scaling limitations of STT-MRAM in the presence of written-in errors and random erasures.

Accordingly, various embodiments of the present invention advantageously provides a memory channel modelling that takes into account (e.g., factors in) one or more types of errors which may be encountered in the memory device, including write errors and read errors in the memory channels (e.g., STT-MRAM channels). In various example embodiments, the write errors in the memory channels are modelled as the output of a BSC with a crossover probability, and read errors in the memory channels are modelled with an erasure probability at the input of the decoder (e.g., LDPC decoder). In various example embodiments, for write errors, a soft-input BSC mapper is provided and configured to deliver soft information with refined reliabilities to the decoder, which has been found to significantly outperform the conventional hard-input BSC mapper. In various example embodiments, for read errors, an erasure-based soft-decision decoder is provided and configured to recover erased bits successively. For example, in example simulations performed, short LDPC codes with the detection and decoding scheme/technique according to example embodiments of the present invention has been found to perform significantly better than the state-of-art BCH codes in STT-MRAM over a wide range of resistance distribution spreads.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A memory device comprising:
a memory cell configured to store an input data bit written thereto;
a memory sensor configured to sense a parameter associated with a state of the memory cell;
a detector configured to determine, based on the parameter sensed from the memory cell, a first soft information indicating the likelihood that the input data bit written to the memory cell is a predefined value; and
a decoder configured to generate an output data bit of the memory cell based on the first soft information,
wherein the detector comprises a first detector configured to determine the first soft information based on a second soft information indicating the likelihood that the state of the memory cell corresponds to a value of the input data bit written to the memory cell.

2. The memory device according to claim 1, wherein the detector further comprises a second detector configured to determine the second soft information based on the parameter sensed from the memory cell.

3. The memory device according to claim 2, wherein the first detector is configured to determine the first soft information based on a log-likelihood ratio of the input data bit based on the second soft information, and the second detector is configured to determine the second soft information based on a log-likelihood ratio of the state of the memory cell based on the parameter sensed from the memory cell.

4. The memory device according to claim 3, wherein the likelihood of the input data bit being correctly written into the memory cell is represented by a binary symmetrical channel (BSC), and wherein the input data bit is an input to the BSC and the state of the memory cell is an output from the BSC.

5. The memory device according to claim 2, wherein the second detector is further configured to determine the second soft information based on the first soft information fed back from the first detector, and the first detector is further configured to determine the first soft information based on a soft information of the output data bit fed back from the decoder.

6. The memory device according to claim 1, further comprising a quantizer configured to convert the parameter sensed from the memory cell into a corresponding one of a plurality of quantization levels to produce a quantized parameter, wherein the detector is configured to determine the first soft information based on the quantized parameter.

7. The memory device according to claim 1, wherein the detector further comprises a third detector configured to detect a read error of the memory cell based on the parameter sensed from the memory cell and to flag a corresponding data bit position as being affected by the read error if the read error of the memory cell is detected.

8. The memory device according to claim 7, comprising a plurality of memory cells configured to store input data bits of an input codeword written thereto, respectively, wherein the decoder comprises a read error corrector configured to receive a plurality of the first soft information determined with respect to the input data bits of the input codeword and to correct at least one of the plurality of the first soft information if the at least one first soft information corresponds to at least one data bit position flagged as being affected by the read error.

9. The memory device according to claim 8, wherein the read error corrector is configured to correct the at least one first soft information based on, at a check node associated with a set of data bit positions in which only one data bit position thereof has been flagged as being affected by the read error, determining a new first soft information for replacing the first soft information corresponding to said one data bit position based on one or more bit-to-check inputs from respective one or more bit nodes to the check node, the respective one or more bit nodes corresponding to one or more data bit positions of the set of data bit positions not flagged as being affected by the read error.

10. The memory device according to claim 1, comprising a plurality of memory cells configured to store input data bits of an input low-density parity-check (LDPC) codeword written thereto, wherein
each of the plurality of memory cells is a spin-transfer torque magnetoresistive random access memory (STT-MRAM) cell,
the state of each of the plurality of memory cells is one of a high resistance state, a low resistance state, and a faulty state,
each of the input data bits has a predefined value of logic ‘1’ or logic ‘0’, and
the decoder is a LDPC decoder.

11. A method of reading a memory device, the memory device comprising a memory cell configured to store an input data bit written thereto, the method comprising:
sensing a parameter associated with a state of the memory cell;
determining, based on the parameter sensed from the memory cell, a first soft information indicating the likelihood that the input data bit written to the memory cell is a predefined value; and
generating an output data bit of the memory cell based on the first soft information,
wherein said determining a first soft information comprises determining the first soft information based on a second soft information indicating the likelihood that the state of the memory cell corresponds to a value of the input data bit written to the memory cell.

12. The method according to claim 11, wherein the second soft information is determined based on the parameter sensed from the memory cell.

13. The method according to claim 12, wherein the first soft information is determined based on a log-likelihood ratio of the input data bit based on the second soft information, and the second soft information is determined based on a log-likelihood ratio of the state of the memory cell based on the parameter sensed from the memory cell.

14. The method according to claim 13, wherein the likelihood of the input data bit being correctly written into the memory cell is represented by a binary symmetrical channel (BSC), and wherein the input data bit is an input to the BSC and the state of the memory cell is an output from the BSC.

15. The method according to claim 12, wherein the second soft information is further determined based on the first soft information fed back from the first detector, and the first soft information is further determined based on a soft information of the output data bit fed back from the decoder.

16. The method according to claim 11, further comprising converting the parameter sensed from the memory cell into a corresponding one of a plurality of quantization levels to produce a quantized parameter, wherein the first soft information is determined based on the quantized parameter.

17. The method according to claim 11, further comprising detecting a read error of the memory cell based on the parameter sensed from the memory cell and flagging a corresponding data bit position as being affected by the read error if the read error of the memory cell is detected.

18. The method according to claim 17, wherein the memory device comprises a plurality of memory cells configured to store input data bits of an input codeword written thereto, respectively, and wherein the method further comprises receiving a plurality of the first soft information determined with respect to the input data bits of the input codeword and correcting at least one of the plurality of the first soft information if the at least one first soft information corresponds to at least one data bit position flagged as being affected by the read error.

19. The method according to claim 18, wherein said correcting at least one of the plurality of the first soft information comprises determining, at a check node associated with a set of data bit positions in which only one data bit position thereof has been flagged as being affected by the read error, a new first soft information for replacing the first soft information corresponding to said one data bit position based on one or more bit-to-check inputs from respective one or more bit nodes to the check node, the respective one or more bit nodes corresponding to one or more data bit positions of the set of data bit positions not flagged as being affected by the read error.

20. A method of forming a memory device, the method comprises:
providing a memory cell configured to store an input data bit written thereto;
forming a memory sensor configured to sense a parameter associated with a state of the memory cell;
forming a detector configured to determine, based on the parameter sensed from the memory cell, a first soft information indicating the likelihood that the input data bit written to the memory cell is a predefined value; and
forming a decoder configured to generate an output data bit of the memory cell based on the first soft information,
wherein the detector comprises a first detector configured to determine the first soft information based on a second soft information indicating the likelihood that the state of the memory cell corresponds to a value of the input data bit written to the memory cell.
